(19) United States
(12) Patent Application Publication
(10) Pub. No.: US 2026/0052655 A1
(43) Pub. Date: Feb. 19, 2026

(54) APPARATUS, SYSTEM, AND METHOD FOR IMPROVING THERMAL CONTACT BETWEEN HEATSINKS AND COMMUNICATION MODULES

(71) Applicant: Juniper Networks, Inc., Sunnyvale, CA (US)

(72) Inventors: Nikola Ikonomov, Millbrae, CA (US); Jimmy Chun-Chuen Leung, Fremont, CA (US); Sriram Gopalaratnam, San Jose, CA (US); Vu L. Le, San Jose, CA (US)

(21) Appl. No.: 19/051,910

(22) Filed: Feb. 12, 2025

Related U.S. Application Data
(60) Provisional application No. 63/682,628, filed on Aug. 13, 2024.

(51) Int. Cl. H05K 7/20

(52) U.S. Cl. CPC H05K 7/2049

(57) ABSTRACT

A disclosed system for improving thermal contact between heatsinks and communication modules may include (1) a plurality of cages dimensioned to house a plurality of communication modules, (2) a plurality of thermal management devices thermally coupled to the plurality of communication modules via the plurality of cages, and (3) a spring-loaded clamp applied between the plurality of thermal management devices, the spring-loaded clamp comprising a spring and a head. Various other apparatuses, systems, and methods are also disclosed.

### CROSS REFERENCE TO RELATED APPLICATION

This application claims the benefit of U.S. Provisional Application No. 63/682,628 filed Aug. 13, 2024, the disclosure of which is incorporated in its entirety by this reference.

### SUMMARY

As will be described in greater detail below, the instant disclosure generally relates to improving thermal contact between heatsinks and communication modules. In one example, a system for accomplishing such a task may include (1) a plurality of cages dimensioned to house a plurality of communication modules, (2) a plurality of thermal management devices thermally coupled to the plurality of communication modules via the plurality of cages, and (3) a spring-loaded clamp applied between the plurality of thermal management devices, the spring-loaded clamp comprising a spring and a head.

Similarly, a corresponding network device may include (1) a plurality of thermal management devices thermally coupled to a plurality of communication modules installed in a plurality of cages and (2) a spring-loaded clamp applied between the plurality of thermal management devices, the spring-loaded clamp comprising a head, a stem, and a spring that facilitates movement of the head relative to the stem.

A corresponding method may include (1) assembling a spring-loaded clamp equipped with a head, a stem, and a spring that facilitates movement of the head relative to the stem and (2) applying the spring-loaded clamp between a plurality of thermal management devices thermally coupled to a plurality of communication modules installed in a plurality of cages.

Features from any of the above-mentioned embodiments may be used in combination with one another in accordance with the general principles described herein. These and other embodiments, features, and advantages will be more fully understood upon reading the following detailed description in conjunction with the accompanying drawings and claims.

### BRIEF DESCRIPTION OF THE DRAWINGS

The accompanying drawings illustrate a number of exemplary embodiments and are a part of the specification. Together with the following description, these drawings demonstrate and explain various principles of the instant disclosure.

FIG. 1 is an illustration of an exemplary system for improving thermal contact between heatsinks and communication modules according to one or more embodiments of this disclosure.

FIG. 2 is an illustration of an exemplary system for improving thermal contact between heatsinks and communication modules according to one or more embodiments of this disclosure.

FIG. 3 is an illustration of an exemplary spring-loaded clamp for improving thermal contact between heatsinks and communication modules according to one or more embodiments of this disclosure.

FIG. 4 is an illustration of an exemplary network device for improving thermal contact between heatsinks and communication modules according to one or more embodiments of this disclosure.

FIG. 5 is an illustration of an exemplary system for improving thermal contact between heatsinks and communication modules according to one or more embodiments of this disclosure.

FIG. 6 is an illustration of an exemplary system for improving thermal contact between heatsinks and communication modules according to one or more embodiments of this disclosure.

FIG. 7 is an illustration of an exemplary system for improving thermal contact between heatsinks and communication modules according to one or more embodiments of this disclosure.

FIG. 8 is an illustration of an exemplary system for improving thermal contact between heatsinks and communication modules according to one or more embodiments of this disclosure.

FIG. 9 is a flow diagram of an exemplary method for improving thermal contact between heatsinks and communication modules according to one or more embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the instant disclosure covers all modifications, equivalents, and alternatives falling within the scope of the appended claims.

### DETAILED DESCRIPTION OF EXEMPLARY EMBODIMENTS

Network devices often include communication modules (such as optical transceivers) that emit heat during operation. To ensure reliable performance, these communication modules may need to stay within a certain temperature range. Accordingly, network device manufacturers may apply heatsinks to the communication modules to remove and/or absorb some of the heat and/or to maintain their temperatures within the reliable range.

Unfortunately, certain applications of such heatsinks may have deficiencies and/or shortcomings. For example, a heatsink may be thermally coupled to an optical module. In this example, the pressure holding the heatsink against the optical module may be non-uniform and/or uneven. This non-uniformity and/or unevenness of the pressure across the heatsink may impede and/or negatively impact the heat transfer from the optical module to the heatsink, thereby potentially causing the optical module to perform sub-optimally and/or causing the optical module to fail altogether.

The instant disclosure, therefore, identifies and addresses a need for apparatuses, systems, and methods that facilitate and/or achieve improved thermal contact between heatsinks and communication modules. As will be explained in greater detail below, embodiments of the instant disclosure may involve a spring-loaded clamp that is inserted and/or applied between two or more heatsinks thermally coupled to two or more optical modules.

In some examples, a network device, such as a router and/or switch, may include and/or represent cages that house and/or hold optical modules. In one example, each cage may include a front entry side that facilitates installation and/or entry of an optical module. In this example, each cage may include and/or form an opening through which a heatsink is applied to make thermal contact with the corresponding optical module. Additionally or alternatively, each cage may be fitted and/or equipped with a heatsink and/or cold plate that makes thermal contact with the corresponding optical module. In certain implementations, a heatsink and/or cold plate may be mounted to each cage for thermally coupling to the corresponding optical module.

In some examples, the network device may include and/or represent an array of cages configured side-by-side with one another. Additionally or alternatively, the network device may include and/or represent an additional array of cages configured side-by-side with one another. In certain implementations, the array and the additional array may be arranged on top of one another in a so-called “belly-to-belly” configuration. In other words, the array and the additional array may be aligned vertically with one another. In certain implementations, the heatsinks mounted to the top array of cages and the heatsinks mounted to the bottom array of cages may oppose each other in the belly-to-belly configuration.

In some examples, a spring-loaded clamp may be applied and/or inserted between two or more heatsinks mounted to two or more optical modules. For example, a spring-loaded clamp may be applied and/or inserted between two heatsinks thermally coupled to two optical modules installed into cages of a single array. In another example, a spring-loaded clamp may be applied and/or inserted between two heatsinks thermally coupled to two optical modules installed into cages of a top array in a belly-to-belly configuration and two heatsinks thermally coupled to two optical modules installed into cages of a bottom array in the belly-to-belly configuration.

In some examples, the spring-loaded clamp may include and/or represent a stem, a head, a spring, and/or a screw. In one example, the spring may be installed and/or applied between the stem and the head. In this example, the screw may be installed and/or applied atop the head to secure the head and/or the spring to the stem. The stem may include and/or represent a brace and/or hook on the side that opposes the screw.

In another example, the spring-loaded clamp may include and/or represent a threaded stem, a head, a spring, and/or a nut. In one example, the spring may be installed and/or applied between the threaded stem and the head. In this example, the nut may be installed and/or applied atop the head to secure the head and/or the spring to the stem.

In some examples, the head may be able to move relative to the stem due to the spring. In one example, the spring may be trapped, held, compressed, and/or maintained between the head and the stem. In this example, the spring may be loaded to create and/or produce force and/or pressure that is applied to the heatsinks mounted to the cages.

In some examples, the spring-loaded clamp may be installed and/or applied such that the stem sits, rests, and/or resides against the circuit board to which the cages are secured and/or coupled. Additionally or alternatively, the spring-loaded clamp may be installed and/or applied such that the stem is braced and/or fixed between the faceplate of the network device and the circuit board to which the cages are secured and/or coupled.

In some examples, each heatsink may be hooked, attached, and/or harnessed (e.g., via a spring) to the backside of the corresponding cage. In one example, each the spring-loaded clamp may be installed and/or applied to balance the force and/or pressure applied toward the backside of the corresponding cage. In certain implementations, the spring-loaded clamp may be configured and/or designed to apply pressure and/or force atop the heatsinks at any particular point and/or area to compensate and/or counterbalance the opposing pressure and/or force.

Examples of the spring installed in the clamp include, without limitation, coil springs, compression springs, tension springs, extension springs, wave springs, Smalley springs, horseshoe springs, torsion springs, constant-force springs, gas springs, canted springs, leaf springs, combinations or variations of one or more of the same, and/or any other suitable spring.

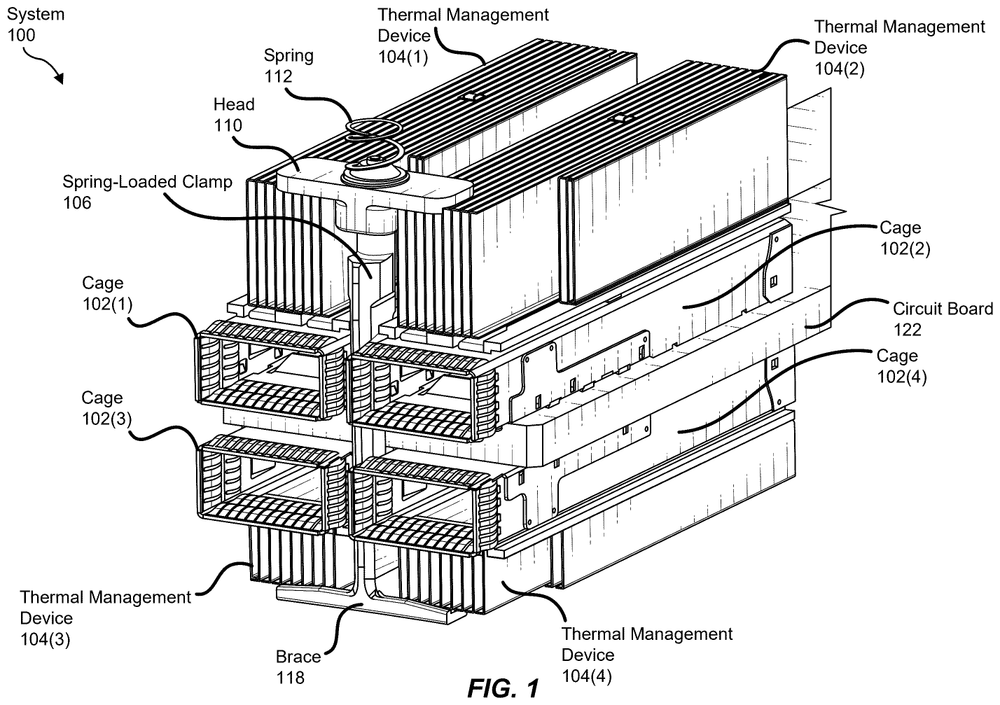

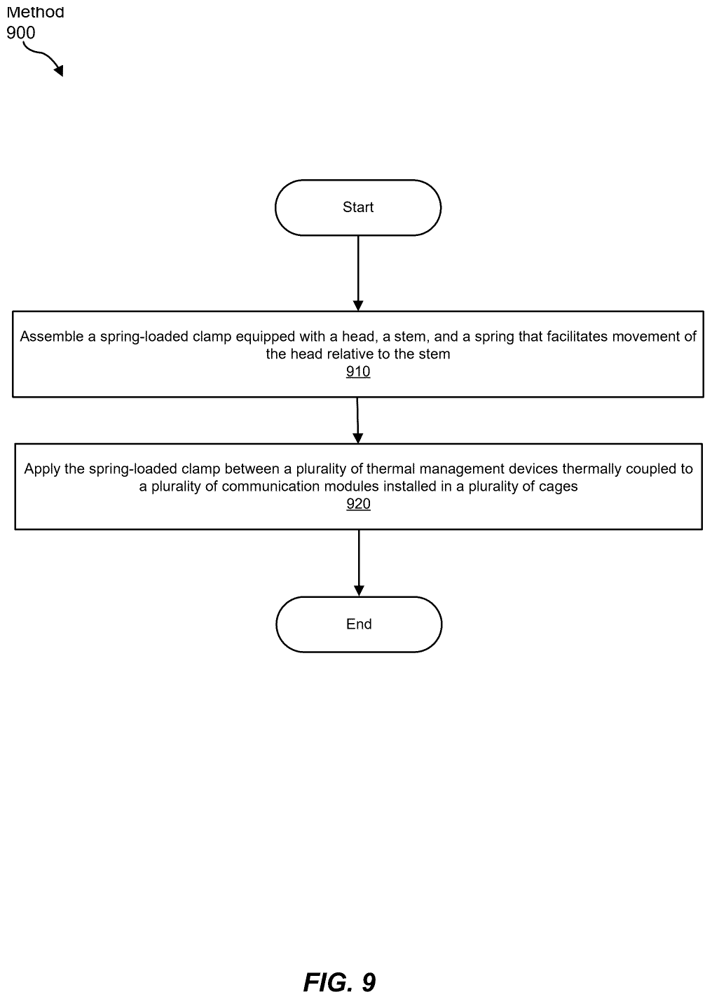

The following will provide, with reference to FIGS. 1-8, detailed descriptions of an exemplary apparatuses, systems, and corresponding implementations and configurations that facilitate and/or support improving thermal contact between heatsinks and communication modules. In addition, the following will provide, with reference to FIG. 9, examples of methods for improving thermal contact between heatsinks and communication modules.

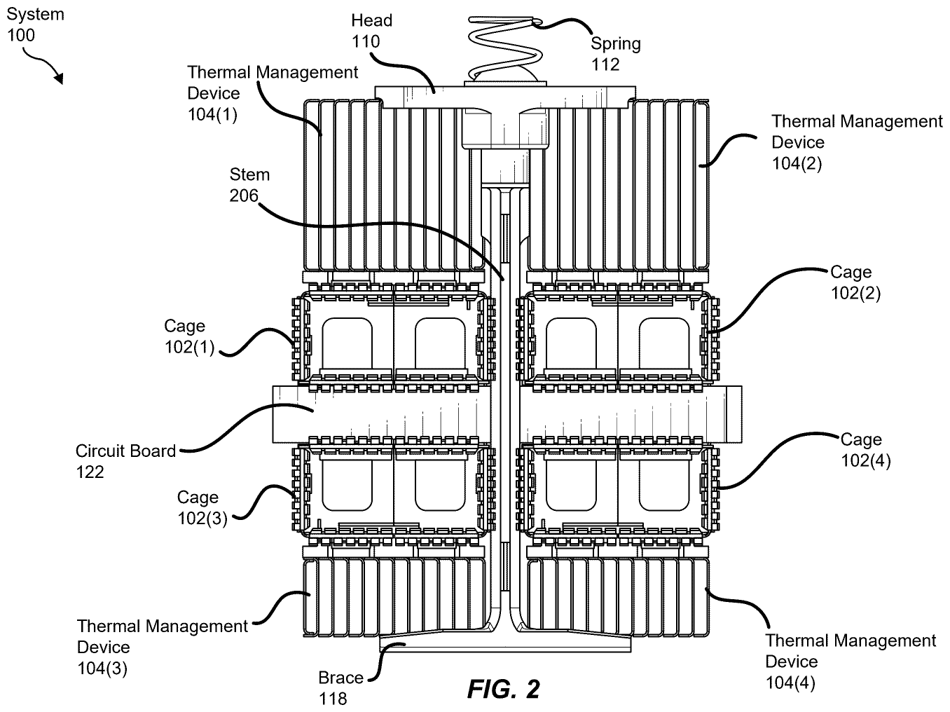

FIGS. 1 and 2 illustrate different views of an exemplary system 100 that provides improved thermal contact between heatsinks and communication modules. As illustrated in FIGS. 1 and 2, system 100 may include and/or represent cages 102(1), 102(2), 102(3), and 102(4), thermal management devices 104(1), 104(2), 104(3), and 104(4), and/or a spring-loaded clamp 106. In some examples, cages 102(1)-(4) may each be dimensioned and/or configured to house and/or accept a communication module (e.g., an optical transceiver). In such examples, thermal management devices 104(1)-(4) may be thermally coupled to such communication modules via cages 102(1)-(4). In one example, spring-loaded clamp 106 may be applied and/or installed between thermal management devices 104(1)-(4).

In some examples, spring-loaded clamp 106 may include and/or represent a head 110, a spring 112, and/or a stem 206 equipped with a fixed brace 118. In one example, spring-loaded clamp 106 may also include and/or represent a screw that mates with a thread formed in stem 206 and/or holds spring 112 moveably in place relative to stem 206. In this example, spring 112 may facilitate, support, and/or provide movement and/or tolerance of head 110 relative to stem 206. Additionally or alternatively, spring 112 may be loaded, activated, and/or compressed to produce a force that is applied and/or imparted to thermal management devices 104(1)-(4). In certain implementations, stem 206 may run, extend, and/or fit between cages 102(1)-(2) and/or between cages 102(3)-(4).

In some examples, head 110 of spring-loaded clamp 106 may be configured and/or assembled to apply the force produced by spring 112 onto a single point of and/or on each of thermal management devices 104(1)-(4). In other examples, head 110 of spring-loaded clamp 106 may be configured and/or assembled to apply the force produced by spring 112 onto multiple points of and/or on each of thermal management devices 104(1)-(4).

In some examples, system 100 may also include and/or represent a circuit board 122 to which cages 102(1)-(4) are coupled, attached, and/or secured. In one example, cages 102(1)-(2) may be arranged, aligned, and/or configured in a row on one side (e.g., the top side) of circuit board 122. In this example, cages 102(3)-(4) may be arranged, aligned, and/or configured in a row on the opposing side (e.g., the bottom side) of circuit board 122.

In some examples, head 110 may be applied to, coupled to, and/or pressed against thermal management devices 104(1)-(2). In such examples, fixed brace 118 may be applied to, coupled to, and/or pressed against thermal management devices 104(3)-(4). In certain implementations, the row of cages 102(1)-(2) and the row of cages 102(3)-(4) may be arranged and/or organized in a belly-to-belly configuration on circuit board 122.

In some examples, cages 102(1)-(4) may be equipped with springs situated toward the backside opposite of the entry point and/or opposite of spring-loaded clamp 106. In one example, such springs may produce and/or provide forces that direct the back regions of thermal management devices 104(1)-(4) downward toward the communication modules installed in cages 102(1)-(4). In this example, spring-loaded clamp 106 may apply and/or produce additional forces that counterbalance and/or oppose those of the springs installed in cages 102(1)-(4). In certain implementations, the additional forces applied and/or produced by spring-loaded clamp 106 may uniformly distribute the thermal couplings and/or contact of thermal management devices 104(1)-(4) across the communication modules installed in cages 102(1)-(4).

In some examples, thermal management devices 104(1)-(4) may thermally interface and/or make thermal contact with the communication modules through openings in cages 102(1)-(4), respectively. In one example, thermal management devices 104(1)-(4) may transfer heat away from the communication modules via dissipation, absorption, convection, radiation, and/or conduction. Examples of thermal management devices 104(1)-(4) include, without limitation, heatsinks, cold plates, fluid-cooled plates, heat exchangers or spreaders, vapor chambers, portions of one or more of the same, combinations or variations of one or more of the same, and/or any other suitable heat-mitigation solutions.

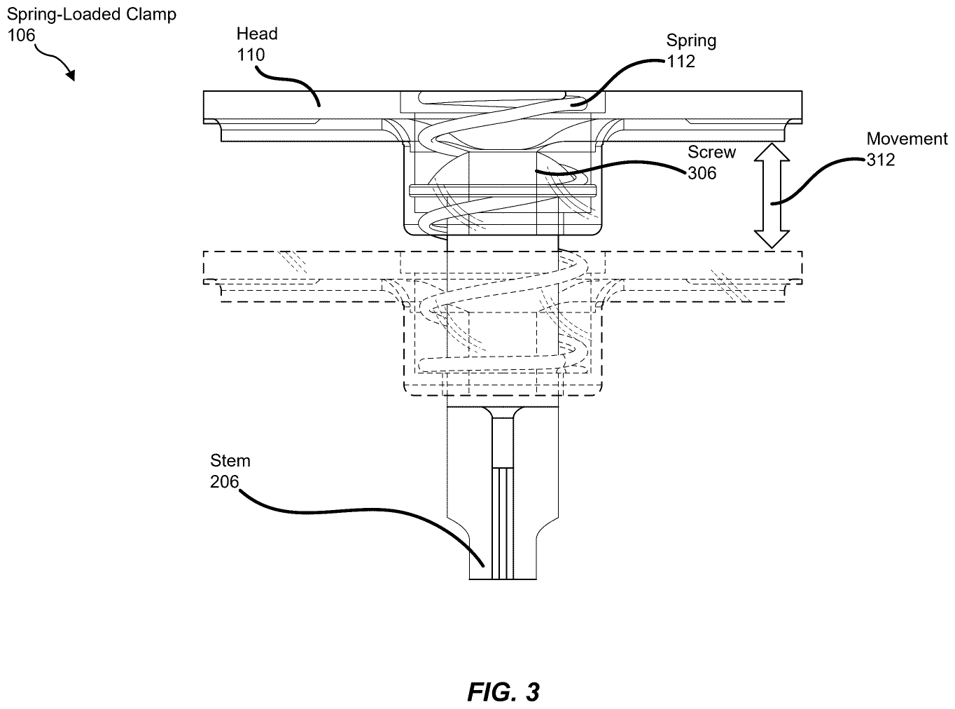

FIG. 3 illustrates an exemplary implementation of a portion of spring-loaded clamp 106. In some examples, spring-loaded clamp 106 may include and/or represent certain mechanisms, components, and/or features that perform and/or provide functionalities that are similar and/or identical to those described above in connection with either FIG. 1 or FIG. 2. In one example, spring-loaded clamp 106 may include and/or represent spring 112 that facilitates, supports, and/or provides movement 312 of head 110 relative to stem 206. In this example, movement 312 may constitute and/or represent motion, travel, and/or tolerance offered and/or provided by spring 112. In certain implementations, spring 112 may be installed and/or applied between head 110 and stem 206 or a screw 306.

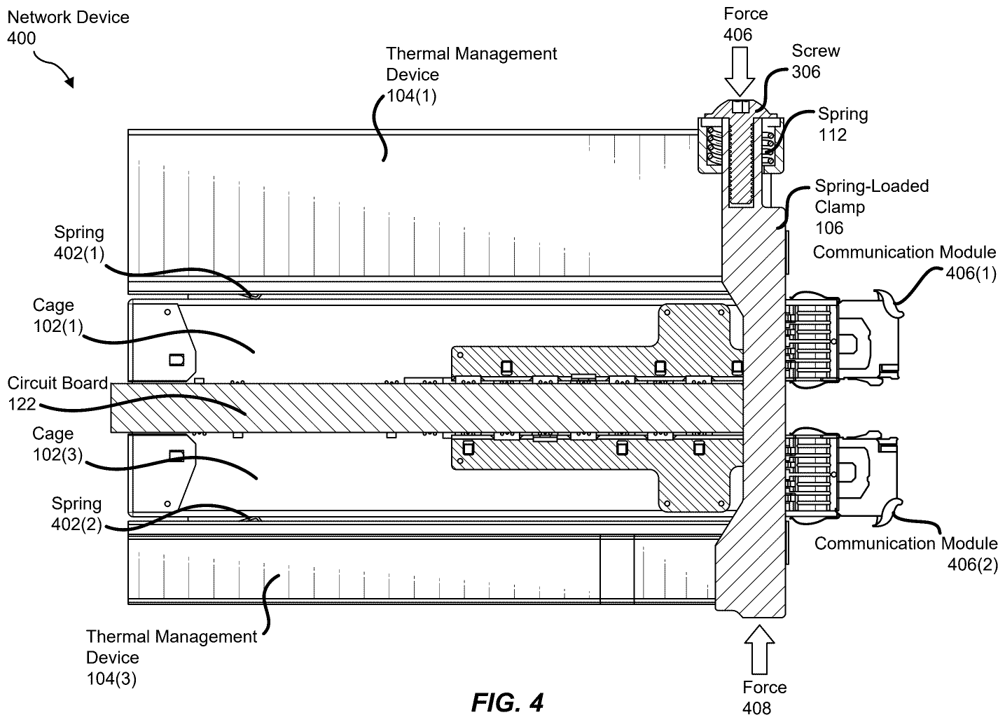

FIG. 4 illustrates a cross section of an exemplary network device 400 that provides improved thermal contact between heatsinks and communication modules. As illustrated in FIG. 4, network device 400 may include and/or represent certain mechanisms, components, and/or features that perform and/or provide functionalities that are similar and/or identical to those described above in connection with any of FIGS. 1-3. In some examples, network device 400 may include and/or represent cages 102(1)-(4), thermal management devices 104(1)-(4), and/or spring-loaded clamp 106. In one example, cages 102(1) and 102(3) may be equipped with springs 402(1) and 402(2), respectively, that are situated toward the backside opposite of the entry point and/or opposite of spring-loaded clamp 106.

In one example, springs 402(1) and 402(2) may produce and/or provide forces that direct the back regions of thermal management devices 104(1) and 104(3) downward toward communication modules 406(1) and 406(2) installed in cages 102(1) and 102(3). In this example, spring-loaded clamp 106 may apply and/or produce forces 406 and 408 that counterbalance and/or oppose those of springs 402(1) and 402(2), respectively. In certain implementations, forces 406 and 408 applied and/or produced by spring-loaded clamp 106 may uniformly distribute the thermal couplings and/or contact of thermal management devices 104(1) and 104(3) across communication modules 406(1) and 406(2) installed in cages 102(1) and 102(3).

In some examples, forces 406 and 408 may be applied and/or imposed at the front of thermal management devices 104(1) and 104(3), respectively, toward the entry points of communication modules 406(1) and 406(2). In one example, forces 406 and 408 may be concentrated into and/or toward a single point and/or area of thermal management devices 104(1) and 104(3), respectively. In certain implementations, spring-loaded clamp 106 may be applied and/or installed to produce and/or provide forces 406 and 408 at any point and/or area (e.g., shifted from the corresponding positions illustrated in FIG. 4) along the corresponding surfaces of thermal management devices 104(1) and 104(3).

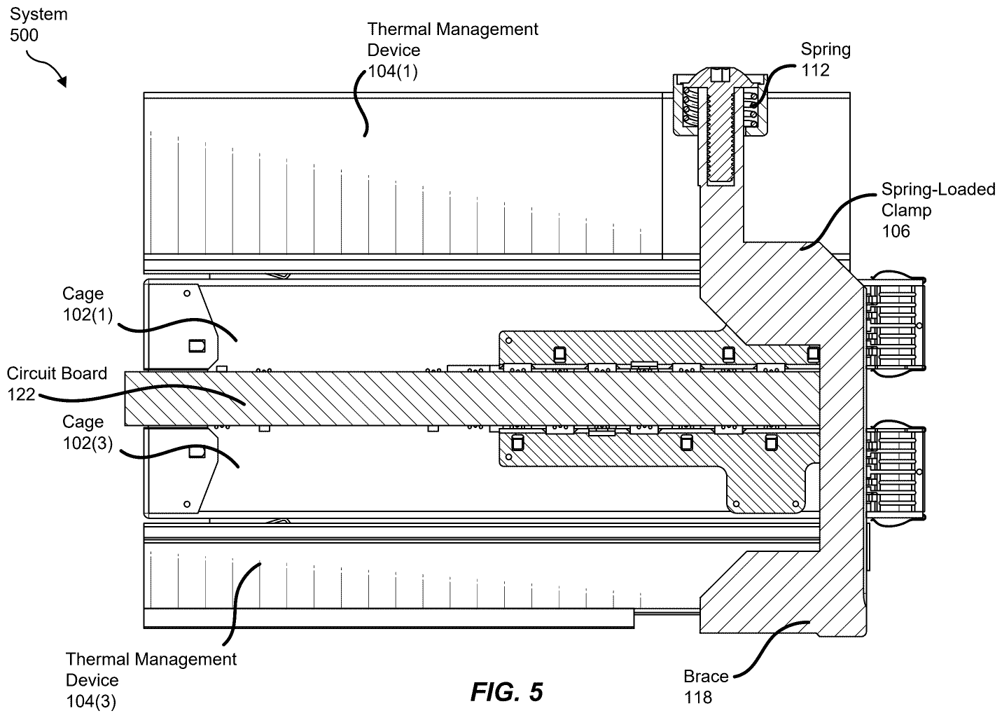

FIG. 5 illustrates a cross section of an exemplary system 500 that provides improved thermal contact between heatsinks and communication modules. As illustrated in FIG. 5, exemplary system 500 may include and/or represent certain mechanisms, components, and/or features that perform and/or provide functionalities that are similar and/or identical to those described above in connection with any of FIGS. 1-4. In some examples, system 500 may include and/or represent cages 102(1)-(4), thermal management devices 104(1)-(4), and/or spring-loaded clamp 106. In one example, spring-loaded clamp 106 in FIG. 5 may constitute and/or represent an implementation in which forces 406 and 408 are shifted from the front of thermal management devices 104(1) and 104(3), as illustrated in FIG. 4, to the center and/or middle of thermal management devices 104(1) and 104(3).

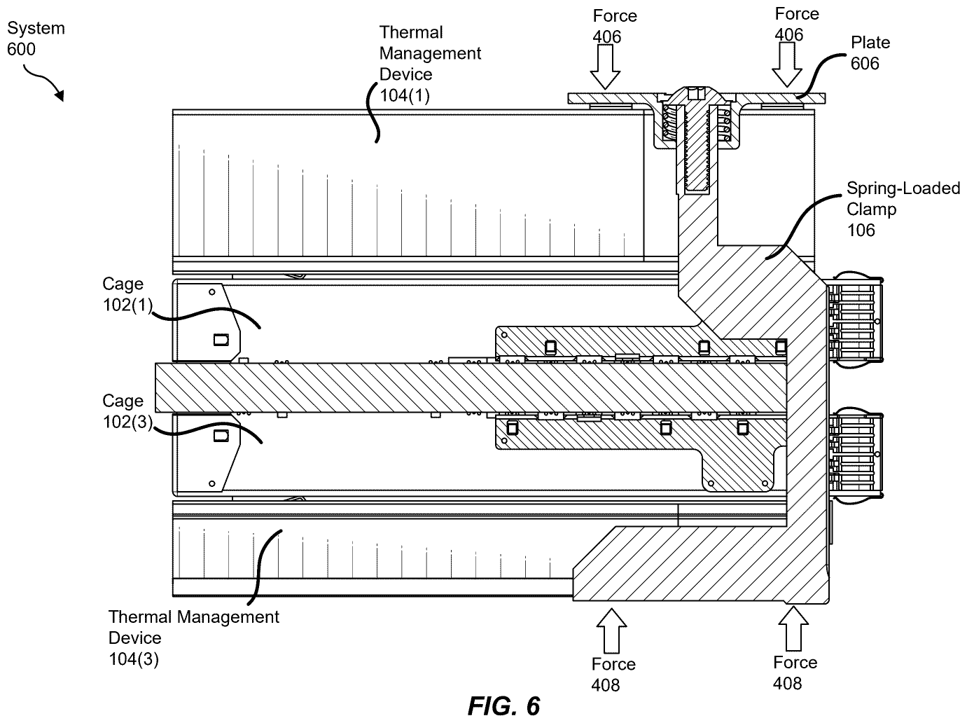

FIG. 6 illustrates a cross section of an exemplary system 600 that provides improved thermal contact between heatsinks and communication modules. As illustrated in FIG. 6, exemplary system 600 may include and/or represent certain mechanisms, components, and/or features that perform and/or provide functionalities that are similar and/or identical to those described above in connection with any of FIGS. 1-5. In some examples, system 500 may include and/or represent cages 102(1)-(4), thermal management devices 104(1)-(4), and/or spring-loaded clamp 106. In one example, spring-loaded clamp 106 in FIG. 5 may constitute and/or represent an implementation in which forces 406 and 408 are distributed onto and/or across multiple points of thermal management devices 104(1) and 104(3), respectively.

In some examples, system 600 may also include and/or represent a plate 606 that distributes, spreads, and/or expands force 406 across multiple points of thermal management device 104(1). In one example, plate 606 may be applied and/or installed in spring-loaded clamp 106. In this example, plate 606 may be installed and/or applied between head 110 and stem 206 or a screw 306. Additionally or alternatively, plate 606 may constitute and/or represent an expansion and/or extension of head 110.

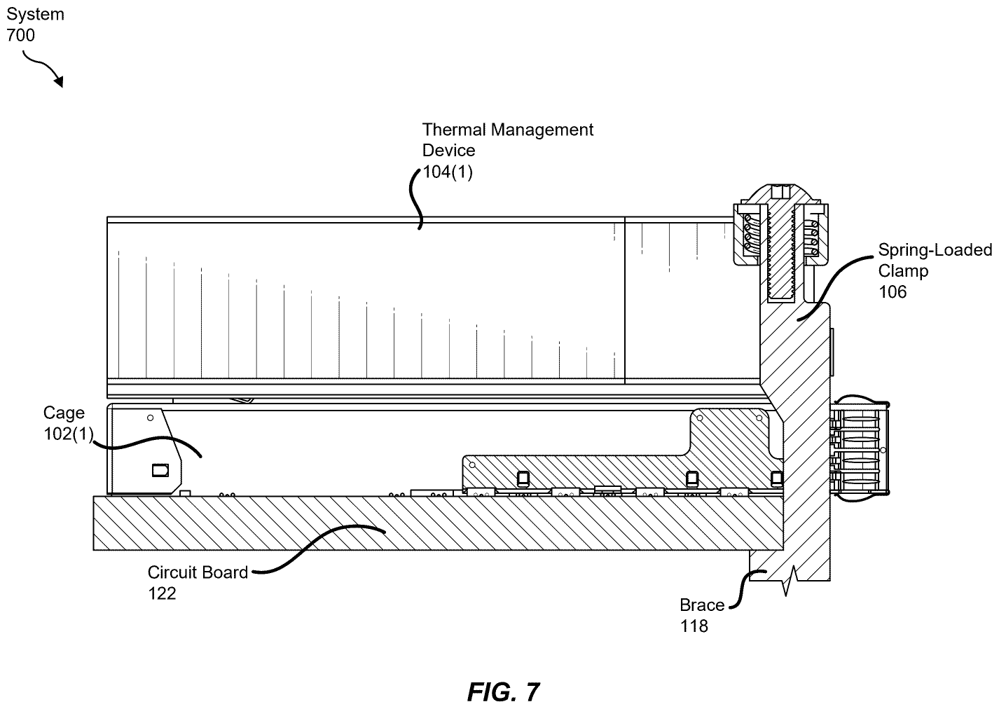

FIG. 7 illustrates a cross section of an exemplary system 700 that provides improved thermal contact between heatsinks and communication modules. As illustrated in FIG. 7, exemplary system 700 may include and/or represent certain mechanisms, components, and/or features that perform and/or provide functionalities that are similar and/or identical to those described above in connection with any of FIGS. 1-6. In some examples, system 700 may include and/or represent cages 102(1)-(2), thermal management devices 104(1)-(2), and/or spring-loaded clamp 106. In one example, unlike many of the implementations described above in connection with FIGS. 1-6, system 700 may include and/or represent a single row of cages 102(1)-(2) disposed along one side of circuit board 122, as opposed to a belly-to-belly configuration. In this example, rather than coupling and/or attaching to thermal management devices 102(3)-(4), fixed brace 118 may be coupled to, attached to, and/or pressed against the opposing side of circuit board 122 to establish spring-loaded tension.

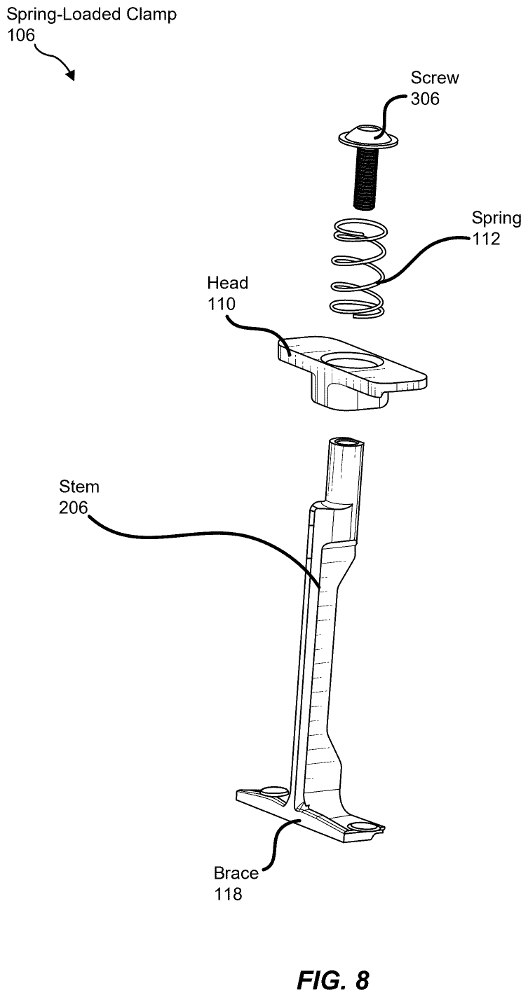

FIG. 8 illustrates an exemplary implementation of spring-loaded clamp 106. In some examples, spring-loaded clamp 106 may include and/or represent certain mechanisms, components, and/or features that perform and/or provide functionalities that are similar and/or identical to those described above in connection with any of FIGS. 1-7. In one example, spring-loaded clamp 106 may include and/or represent spring 112 that facilitates, supports, and/or provides movement 312 of head 110 relative to stem 206. In this example, head 110 may be placed and/or positioned atop, over, and/or through stem 206. In certain implementations, spring 112 may be placed and/or positioned atop, over, and/or through head 110. Additionally or alternatively, screw 306 may be placed and/or positioned atop, over, and/or through spring 112 and mate with stem 206.

In some examples, head 110 may be able to move relative to stem 206 via spring 112. In one example, spring 112 may be trapped, held, compressed, and/or maintained between screw 306 and head 110 and/or stem 206. In this example, when spring-loaded clamp 106 is installed on and/or between thermal management devices 104(1)-(4) to improve thermal contact, spring 112 may be loaded and/or compressed to create and/or produce force and/or pressure that is applied to thermal management devices 104(1)-(4).

In some examples, the various apparatuses, systems, and/or devices described in connection with FIGS. 1-8 may include and/or represent one or more additional mechanisms, components, and/or features that are not necessarily illustrated and/or labeled in FIGS. 1-8. For example, any of the apparatuses, systems, and/or devices in FIGS. 1-8 may also include and/or represent additional analog and/or digital circuitry, onboard logic, transistors, antennas, resistors, capacitors, diodes, inductors, switches, registers, flipflops, connections, traces, buses, semiconductor (e.g., silicon) devices and/or structures, processing devices, storage devices, circuit boards, packages, substrates, housings, attachment mechanisms, springs, heat-mitigation devices, cages, combinations or variations of one or more of the same, and/or any other suitable components.

FIG. 9 is a flow diagram of an exemplary computer-implemented method 900 for improving thermal contact between heatsinks and communication modules. In one example, the steps shown in FIG. 9 may be achieved and/or accomplished by a computing equipment manufacturer or subcontractor that assembles and/or manufactures the apparatuses, systems, and/or devices described herein. Additionally or alternatively, the steps shown in FIG. 9 may incorporate and/or involve certain sub-steps and/or variations consistent with the descriptions provided above in connection with FIGS. 1-8.

FIG. 9 is a flow diagram of an exemplary method 900 for improving thermal contact between heatsinks and communication modules. Method 900 may include the step of assembling a spring-loaded clamp equipped with a head, a stem, and/or a spring that facilitates movement of the head relative to the stem (910). Step 910 may be performed in a variety of ways, including any of those described above in connection with FIGS. 1-8. For example, a computing equipment manufacturer or subcontractor may assemble a spring-loaded clamp equipped with a head, a stem, and/or a spring that facilitates movement of the head relative to the stem.

Method 900 may also include the step of applying the spring-loaded clamp between a plurality of thermal management devices thermally coupled to a plurality of communication modules installed in a plurality of cages (920). Step 920 may be performed in a variety of ways, including any of those described above in connection with FIGS. 1-8. For example, the computing equipment manufacturer or subcontractor may apply the spring-loaded clamp between a plurality of thermal management devices thermally coupled to a plurality of communication modules installed in a plurality of cages.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered exemplary in nature since many other architectures can be implemented to achieve the same functionality.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A system comprising:
a plurality of cages dimensioned to house a plurality of communication modules;
a plurality of thermal management devices thermally coupled to the plurality of communication modules via the plurality of cages; and
a spring-loaded clamp applied between the plurality of thermal management devices, the spring-loaded clamp comprising:
a spring; and
a head.

2. The system of claim 1, wherein the spring-loaded clamp further comprises a stem equipped with a fixed brace positioned opposite the head.

3. The system of claim 2, wherein the spring facilitates movement of the head relative to the stem.

4. The system of claim 2, wherein the spring is loaded to produce a force that is applied to the plurality of thermal management devices.

5. The system of claim 4, wherein the head of the spring-loaded clamp is configured to apply the force produced by the spring onto a single point of each of the thermal management devices.

6. The system of claim 4, wherein the head of the spring-loaded clamp is configured to apply the force produced by the spring onto multiple points of each of the thermal management devices.

7. The system of claim 2, wherein the spring-loaded clamp further comprises a screw that:
mates with a thread formed in the stem; and
holds the spring moveably in place relative to the stem.

8. The system of claim 2, further comprising a circuit board to which the plurality of cages are coupled, wherein:
a first row of the cages houses a first set of the communication modules and is arranged on one side of the circuit board;
a second row of the cages houses a second set of the communication modules and is arranged on an opposing side of the circuit board;
the head is applied to a first row of the thermal management devices thermally coupled to the first set of communication modules; and
the fixed brace is applied to a second row of the thermal management devices thermally coupled to the second set of communication modules.

9. The system of claim 8, wherein the first row of cages and the second row of cages are arranged in a belly-to-belly configuration on the circuit board.

10. The system of claim 1, wherein the plurality of thermal management devices comprises either:
a set of two thermal management devices; or
a set of four thermal management devices.

11. The system of claim 1, wherein the plurality of cages are equipped with springs whose forces direct back regions of the thermal management devices toward the plurality of communication modules.

12. The system of claim 11, wherein the spring-loaded clamp applies additional forces to front regions of the thermal management devices, the additional forces counterbalancing the forces to uniformly distribute the thermal couplings of the thermal management devices across the plurality of communication devices.

13. A network device comprising:
a plurality of thermal management devices thermally coupled to a plurality of communication modules installed in a plurality of cages; and
a spring-loaded clamp applied between the plurality of thermal management devices, the spring-loaded clamp comprising:
a head;
a stem; and
a spring that facilitates movement of the head relative to the stem.

14. The network device of claim 13, wherein the spring-loaded clamp further comprises a stem equipped with a fixed brace positioned opposite the head.

15. The network device of claim 14, wherein the spring facilitates movement of the head relative to the stem.

16. The network device of claim 14, wherein the spring is loaded to produce a force that is applied to the plurality of thermal management devices.

17. The network device of claim 16, wherein the head of the spring-loaded clamp is configured to apply the force produced by the spring onto a single point of each of the thermal management devices.

18. The network device of claim 16, wherein the head of the spring-loaded clamp is configured to apply the force produced by the spring onto multiple points of each of the thermal management devices.

19. The network device of claim 14, wherein the spring-loaded clamp further comprises a screw that:
mates with a thread formed in the stem; and
holds the spring moveably in place relative to the stem.

20. A method comprising:
assembling a spring-loaded clamp equipped with:
a head;
a stem; and
a spring that facilitates movement of the head relative to the stem; and
applying the spring-loaded clamp between a plurality of thermal management devices thermally coupled to a plurality of communication modules installed in a plurality of cages.
